(19) United States
(12) Patent Application Publication
(10) Pub. No.: US 2025/0106989 A1
(43) Pub. Date: Mar. 27, 2025

(54) STRETCHABLE WIRING SUBSTRATE

(71) Applicant: Murata Manufacturing Co., Ltd., Nagaokakyo-shi (JP)

(72) Inventor: Hayato KATSU, Nagaokakyo-shi (JP)

(21) Appl. No.: 18/976,618

(22) Filed: Dec. 11, 2024

Related U.S. Application Data
(63) Continuation of application No. PCT/JP2023/021501, filed on Jun. 9, 2023.

(30) Foreign Application Priority Data
Jun. 20, 2022 (JP) 2022-098927

(51) Int. Cl. H05K 1/02

(52) U.S. Cl. CPC H05K 1/0283; H05K 1/0268

(57) ABSTRACT

A stretchable wiring board that includes: a stretchable substrate having a first main surface and a second main surface facing each other in a thickness direction; and a wiring member on at least the first main surface side of the stretchable substrate and including at least one stretchable wiring extending in a plane direction including a length direction orthogonal to the thickness direction and a width direction orthogonal to the thickness direction and the length direction, wherein the at least one stretchable wiring includes a first wiring portion and a second wiring portion both extending in the length direction, at least the first wiring portion is an electric path to an outside of the stretchable wiring board, and a tensile strength in the length direction of the second wiring portion is lower than a tensile strength in the length direction of the first wiring portion.

### CROSS REFERENCE TO RELATED APPLICATIONS

The present application is a continuation of International application No. PCT/JP2023/021501, filed Jun. 9, 2023, which claims priority to Japanese Patent Application No. 2022-098927, filed Jun. 20, 2022, the entire contents of each of which are incorporated herein by reference.

### TECHNICAL FIELD

The present disclosure relates to a stretchable wiring board.

### BACKGROUND ART

Patent Document 1 discloses a code-shaped temperature fuse in which a linear fuse is arranged in an insulating coated tube, and the linear fuse is bent in a shape having stretchability in a longitudinal direction of the linear fuse.
Patent Document 1: Japanese Patent Application Laid-Open No. H10-188756

### SUMMARY OF THE DISCLOSURE

In recent years, a state or the like of a human body has been managed by acquiring and analyzing biological information (vital signs) by using a stretchable wiring board. In a case where the stretchable wiring board is used in a state of being attached to a human body, for example, a wiring used for the stretchable wiring board is required to have stretchability that follows movement of a human body. That is, a wiring used for the stretchable wiring board is required to be a stretchable wiring having stretchability.

However, if a wiring used for the stretchable wiring board is a stretchable wiring, and if the stretchable wiring board is stretched more than expected, resistance of the stretchable wiring is likely to increase along with the stretch of the stretchable wiring board. When resistance of the stretchable wiring increases in this manner, in a case where excessive current flows through the stretchable wiring, the stretchable wiring may generate heat and be easily disconnected. Furthermore, when the stretchable wiring board is used in a state in which resistance of the stretchable wiring is high, there is a possibility that an error occurs in biological information to be acquired, or when excessive current flows through the stretchable wiring, heat is generated and an adverse effect, such as a burn, is caused on a human body.

On the other hand, by incorporating a stretchable fuse such as a code-shaped temperature fuse described in Patent Document 1 into a stretchable wiring board, it is conceivable to have a mechanism in which the stretchable wiring board is electrically broken by blowing of the fuse when overcurrent flows through the stretchable wiring in a state in which the stretchable wiring board is excessively stretched more than expected. However, it is technically difficult to incorporate a code-shaped temperature fuse having a hollow structure described in FIG. 1 and the like of Patent Document 1 into a stretchable wiring board. If the code-shaped temperature fuse described in Patent Document 1 can be incorporated into a stretchable wiring board, the stretchable wiring board has high temperature when the code-shaped temperature fuse is blown, which may adversely affect a human body.

From the above, in a case where a stretchable wiring board is used in a state of being attached to a human body, a mechanism capable of safely detecting an excessively stretched state of the stretchable wiring board is required.

The present disclosure has been made to solve the above problem, and an object of the present disclosure is to provide a stretchable wiring board that allows an excessively stretched state to be safely detected.

A stretchable wiring board of the present disclosure includes: a stretchable substrate having a first main surface and a second main surface facing each other in a thickness direction; and a wiring member on at least the first main surface side of the stretchable substrate and including at least one stretchable wiring extending in a plane direction including a length direction orthogonal to the thickness direction and a width direction orthogonal to the thickness direction and the length direction, wherein the at least one stretchable wiring includes a first wiring portion and a second wiring portion both extending in the length direction, at least the first wiring portion is an electric path to an outside of the stretchable wiring board, and a tensile strength in the length direction of the second wiring portion is lower than a tensile strength in the length direction of the first wiring portion.

According to the present disclosure, it is possible to provide a stretchable wiring board that allows an excessively stretched state to be safely detected.

### BRIEF EXPLANATION OF THE DRAWINGS

FIG. 1 is a perspective view schematically illustrating an example of a stretchable wiring board of a first embodiment of the present disclosure.

FIG. 2 is a schematic perspective view illustrating an example of the stretchable wiring board according to a variation of the first embodiment of the present disclosure.

FIG. 3 is a perspective view schematically illustrating an example of the stretchable wiring board of a second embodiment of the present disclosure.

FIG. 4 is a schematic perspective view illustrating an example of the stretchable wiring board according to a variation of the second embodiment of the present disclosure.

FIG. 5 is a perspective view schematically illustrating an example of the stretchable wiring board of a third embodiment of the present disclosure.

FIG. 6 is a schematic perspective view illustrating an example of the stretchable wiring board according to a variation of the third embodiment of the present disclosure.

FIG. 7 is a flowchart illustrating an example of operation of the stretchable wiring board according to a fourth embodiment of the present disclosure.

FIG. 8 is a flowchart illustrating an example of operation of the stretchable wiring board according to a variation of the fourth embodiment of the present disclosure.

### DESCRIPTION OF THE PREFERRED EMBODIMENTS

Hereinafter, a stretchable wiring board of the present disclosure will be described. The present disclosure is not limited to a configuration below, and may be modified as appropriate without departing from the gist of the present disclosure. Further, a combination of a plurality of individual preferable configurations described below is also the present disclosure.

It goes without saying that each of the embodiments illustrated below is an example, and partial replacement or combination of configurations illustrated in different embodiments is possible. In a second embodiment and subsequent embodiments, matters common to a first embodiment will not be described, and only a different point will be mainly described. In particular, the same operation and effect by the same configuration will not be sequentially mentioned for each embodiment.

The drawings shown below are schematic views, and dimensions, scales of aspect ratios, and the like may be different from those of actual products.

A stretchable wiring board of the present disclosure includes: a stretchable substrate having a first main surface and a second main surface facing each other in a thickness direction; and a wiring member on at least the first main surface side of the stretchable substrate and including at least one stretchable wiring extending in a plane direction including a length direction orthogonal to the thickness direction and a width direction orthogonal to the thickness direction and the length direction, wherein the at least one stretchable wiring includes a first wiring portion and a second wiring portion both extending in the length direction, at least the first wiring portion is an electric path to an outside of the stretchable wiring board, and a tensile strength in the length direction of the second wiring portion is lower than a tensile strength in the length direction of the first wiring portion.

### First Embodiment

In the stretchable wiring board according to the first embodiment of the present disclosure, the first wiring portion and the second wiring portion are provided on the different stretchable wirings.

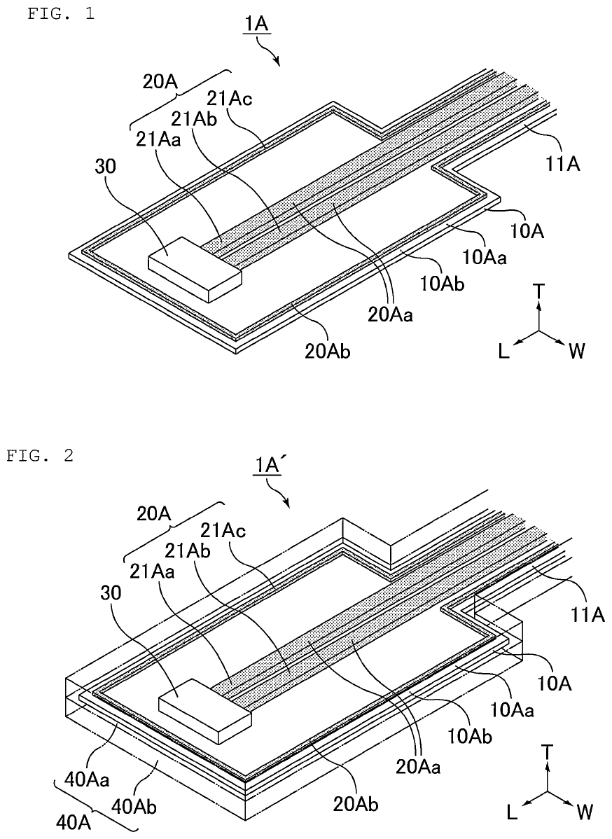

FIG. 1 is a perspective view schematically illustrating an example of a stretchable wiring board of the first embodiment of the present disclosure.

A stretchable wiring board 1A illustrated in FIG. 1 includes a stretchable substrate 10A and a wiring member 20A.

In the present description, a length direction, a thickness direction, and a width direction are respectively defined as L, T, and W, as illustrated in FIG. 1 and the like. The length direction L, the thickness direction T, and the width direction W are orthogonal to each other. Further, a direction orthogonal to the thickness direction T and including the length direction L and the width direction W is defined as a plane direction.

In the present description, various dimensions in the length direction, the thickness direction, and the width direction are indicated as those in a state in which the stretchable wiring board is not stretched or contracted unless otherwise specified. Each of various dimensions in the length direction, the thickness direction, and the width direction is measured by viewing the stretchable wiring board in plan view or sectional view with an optical microscope.

The stretchable substrate 10A has a first main surface 10Aa and a second main surface 10Ab facing each other in the thickness direction T.

The stretchable substrate 10A has a narrow portion 11A having a smallest sectional area when a section orthogonal to the length direction L is viewed.

In the example illustrated in FIG. 1, a dimension in the thickness direction T of the stretchable substrate 10A is constant regardless of a position along the length direction L. That is, in the example illustrated in FIG. 1, the narrow portion 11A corresponds to a portion having a smallest dimension in the width direction W of the stretchable substrate 10A. Note that in a case where a dimension in the width direction W of the stretchable substrate 10A is constant regardless of a position along the length direction L, the narrow portion 11A corresponds to, for example, a portion having a smallest dimension in the thickness direction T of the stretchable substrate 10A. As described above, the narrow portion 11A only needs to be a portion having a smallest sectional area of the stretchable substrate 10A when a section orthogonal to the length direction L is viewed, and various dimensions and the like of the narrow portion 11A are not particularly limited.

The stretchable substrate 10A preferably contains at least one type of resin selected from a group including styrene-based resin, olefin-based resin, and silicone-based resin. Examples of the styrene-based resin include styrene-butadiene-styrene copolymer resin (SBS).

A dimension in the thickness direction T of the stretchable substrate 10A is preferably 100 μm or less, and more preferably 50 μm or less. As a dimension in the thickness direction T of the stretchable substrate 10A is in the above range, the stretchable wiring board 1A easily follows movement of a human body in a case where the stretchable wiring board 1A is used in a state of being attached to the human body.

A dimension in the thickness direction T of the stretchable substrate 10A is preferably 10 μm or more.

A breaking elongation rate in the length direction L of the stretchable substrate 10A is preferably 50% or more. As a breaking elongation rate in the length direction L of the stretchable substrate 10A is in the above range, the stretchable wiring board 1A easily follows movement of a human body in a case where the stretchable wiring board 1A is used in a state of being attached to the human body.

From the viewpoint that the stretchable wiring board 1A easily follows movement of the human body, a breaking elongation rate in the length direction L of the stretchable substrate 10A is preferably on the higher end of the range of 50% or more.

Young's modulus of the stretchable substrate 10A is preferably 100 MPa or less, and more preferably 30 MPa or less. As Young's modulus of the stretchable substrate 10A is in the above range, the stretchable wiring board 1A is less likely to inhibit stretching and contraction of a surface of a human body in a case of being used in a state where the stretchable wiring board 1A is attached to the human body, so that discomfort due to the stretchable wiring board 1A is less likely to occur.

Young's modulus of the stretchable substrate 10A is preferably 3 MPa or more.

In the example illustrated in FIG. 1, a shape of the stretchable substrate 10A when viewed from the thickness direction T is a shape in which a dimension in the width direction W is larger at one end portion than another portion.

Note that a shape of the stretchable substrate 10A when viewed from the thickness direction T may be a shape in which a dimension in the width direction W is constant regardless of a position along the length direction L.

Further, a shape of the stretchable substrate 10A when viewed from the thickness direction T may be a shape in which one end portion has a loop shape, for example, a shape in which a linear portion and a loop-shaped portion are connected in the length direction L. In this case, the stretchable substrate 10A may have a narrow portion at a position where the linear portion and the loop-shaped portion are connected.

The wiring member 20A is provided on at least the first main surface 10Aa side of the stretchable substrate 10A.

In the example illustrated in FIG. 1, the wiring member 20A is provided on the first main surface 10Aa side of the stretchable substrate 10A.

Note that the wiring member 20A may be provided on the second main surface 10Ab side of the stretchable substrate 10A in addition to the first main surface 10Aa side of the stretchable substrate 10A.

In the example illustrated in FIG. 1, the wiring member 20A is provided on the first main surface 10Aa of the stretchable substrate 10A. That is, in the example illustrated in FIG. 1, the stretchable substrate 10A and the wiring member 20A are in contact with each other.

Note that another member may be interposed between the stretchable substrate 10A and the wiring member 20A.

The wiring member 20A includes at least one stretchable wiring extending in the plane direction including the length direction L and the width direction W.

In the example illustrated in FIG. 1, the wiring member 20A includes three stretchable wirings, a stretchable wiring 21Aa, a stretchable wiring 21Ab, and a stretchable wiring 21Ac, extending in the plane direction.

Note that the wiring member 20A may include only one stretchable wiring, may include two stretchable wirings, or may include four or more stretchable wirings.

A dimension in the thickness direction T of the stretchable wiring 21Aa, the stretchable wiring 21Ab, and the stretchable wiring 21Ac in the example illustrated in FIG. 1, is preferably 100 μm or less, and more preferably 50 μm or less. As a dimension in the thickness direction T of the stretchable wiring is in the above range, the stretchable wiring board 1A easily follows movement of a human body in a case where the stretchable wiring board 1A is used in a state of being attached to the human body.

A dimension in the thickness direction T of the stretchable wiring 21Aa, the stretchable wiring 21Ab, and the stretchable wiring 21Ac in the example illustrated in FIG. 1, is preferably 1 μm or more, and more preferably 10 μm or more.

The stretchable wiring 21Aa, the stretchable wiring 21Ab, and the stretchable wiring 21Ac in the example illustrated in FIG. 1 contain, for example, conductive particles and resin.

Examples of a constituent material of the conductive particles contained in the stretchable wiring include metal such as silver, copper, and nickel. Among them, silver is preferable from the viewpoint of achieving low resistance of the stretchable wiring.

An average particle size of the conductive particles contained in the stretchable wiring is preferably 0.01 μm to 10 μm.

An average particle size of the conductive particles contained in the stretchable wiring is determined as described below. First, a stretchable wiring board or the like is polished, so that a section in which a target stretchable wiring is exposed appears. Next, an image of the section is shot with a scanning electron microscope (SEM) or the like. Then, image analysis of the shot sectional image is performed to measure an equivalent circular diameter of the conductive particles contained in the stretchable wiring, and the obtained equivalent circular diameter is taken as a particle size of the conductive particles. After the above, number-based cumulative particle size distribution is determined from the obtained particle sizes of the conductive particles, and a particle size (median diameter D₅₀) at which cumulative probability is 50% in the number-based cumulative particle size distribution is determined as an average particle size of the conductive particles.

A shape of the conductive particles contained in the stretchable wiring is preferably spherical. A shape of the conductive particles contained in the stretchable wiring may be a flat shape, an irregular shape having a protrusion, or the like, in addition to a spherical shape, from the viewpoint of reducing a resistance change of the stretchable wiring with respect to stretching and contraction.

In a case where the wiring member 20A includes a plurality of stretchable wirings, the conductive particles contained in each of the stretchable wirings are preferably the same as each other at least in terms of a type of constituent material, but may be different from each other or a part of them may be different from each other.

Resin contained in the stretchable wiring is preferably at least one type of elastomer resin selected from a group including an epoxy-based resin, a urethane-based resin, an acrylic resin, and a silicone-based resin. In this case, stretchability of the stretchable wiring is easily secured. Note that the resin contained in the stretchable wiring may be resin other than the above as long as the resin can impart a stretchable function.

In a case where the wiring member 20A includes a plurality of stretchable wirings, resin contained in each of the stretchable wirings is preferably the same as each other at least in terms of a type, but may be different from each other or a part of the resin may be different from each other.

The stretchable wirings, the stretchable wiring 21Aa, the stretchable wiring 21Ab, and the stretchable wiring 21Ac in the example illustrated in FIG. 1, are formed, for example, as described below. First, conductive paste containing conductive particles and resin is applied to at least the first main surface 10Aa of the stretchable substrate 10A. Examples of a method of applying the conductive paste include a screen printing method, an inkjet method, and a dispensing method. Then, the applied conductive paste is heat-treated to form the stretchable wiring.

The wiring member 20A includes a first wiring portion 20Aa and a second wiring portion 20Ab both extending in the length direction L.

In the present description, a wiring portion (stretchable wiring) of a wiring member extending in the length direction means that the wiring portion (stretchable wiring) has a portion extending substantially in the length direction when the entire wiring member is viewed. Note that a wiring portion (stretchable wiring) of a wiring member may also have a portion extending in a direction other than the length direction (for example, in the width direction) as long as the wiring portion has a portion extending substantially in the length direction.

The first wiring portion 20Aa and the second wiring portion 20Ab are provided on different stretchable wirings.

In the example illustrated in FIG. 1, the first wiring portion 20Aa is provided on the stretchable wiring 21Aa and the stretchable wiring 21Ab, and the second wiring portion 20Ab is provided on the stretchable wiring 21Ac. More specifically, the first wiring portion 20Aa corresponds to the entire stretchable wiring 21Aa and stretchable wiring 21Ab, and the second wiring portion 20Ab corresponds to the entire stretchable wiring 21Ac.

The first wiring portion 20Aa, each of the stretchable wiring 21Aa and the stretchable wiring 21Ab in the example illustrated in FIG. 1, is electrically connected to an electronic component 30. That is, the first wiring portion 20Aa constitutes an electric path to the outside, that is, an electric path to the external electronic component 30 in the example illustrated in FIG. 1.

The electronic component 30 is mounted on the first wiring portion 20Aa, each of the stretchable wiring 21Aa and the stretchable wiring 21Ab in the example illustrated in FIG. 1, via a bonding member such as solder.

Examples of the electronic component 30 include a diode, an integrated circuit (IC), a capacitor, a resistor, an inductor, and an amplifier (an operational amplifier, a transistor, or the like).

For example, in a case where a light emitting diode, which is a type of diode, is used as the electronic component 30, the first wiring portion 20Aa, the stretchable wiring 21Aa and the stretchable wiring 21Ab in the example illustrated in FIG. 1 function as a drive wiring through which large current for driving the light emitting diode flows. In this case, when the stretchable wiring board 1A is excessively stretched in the length direction L, resistance of the first wiring portion 20Aa becomes too high along with the stretching of the first wiring portion 20Aa, and, for this reason, there is a possibility that large current for driving a light emitting diode does not easily flow to the light emitting diode via the first wiring portion 20Aa, the first wiring portion 20Aa is easily disconnected when large current flows, or the first wiring portion 20Aa easily generates heat when large current flows. As described above, when the stretchable wiring board 1A is excessively stretched in the length direction L as described above, there is a possibility that a light emitting diode as the electronic component 30 is not turned on, or the first wiring portion 20Aa excessively generates heat.

On the other hand, in the stretchable wiring board 1A, in the wiring member 20A, the second wiring portion 20Ab is provided in addition to the first wiring portion 20Aa, and in the wiring member 20A, tensile strength in the length direction L of the second wiring portion 20Ab is lower than tensile strength in the length direction L of a portion other than the second wiring portion 20Ab including the first wiring portion 20Aa. That is, the tensile strength in the length direction L of the second wiring portion 20Ab is not only lower than the tensile strength in the length direction L of the first wiring portion 20Aa, but also lowest among tensile strengths in the length direction L of the wiring member 20A. By the above, when the stretchable wiring board 1A is stretched in the length direction L, the second wiring portion 20Ab is not only disconnected earlier than the first wiring portion 20Aa, but also disconnected first in the wiring member 20A.

Therefore, in the stretchable wiring board 1A, disconnection of the second wiring portion 20Ab is detected by utilizing the fact that the second wiring portion 20Ab is first disconnected when the stretchable wiring board 1A is stretched in the length direction L, so that it is possible to detect an excessively stretched state of the stretchable wiring board 1A in which the stretchable wiring board 1A is excessively stretched in the length direction L before a trouble such as disconnection of the first wiring portion 20Aa occurs due to the first wiring portion 20Aa being excessively stretched in the length direction L.

Furthermore, when the stretchable wiring board 1A is used, it is possible to prompt the user to stop using the stretchable wiring board 1A at a time point at which disconnection of the second wiring portion 20Ab is detected when the stretchable wiring board 1A is stretched in the length direction L, that is, at a time point before the first wiring portion 20Aa is excessively stretched in the length direction L. That is, when the stretchable wiring board 1A is used, when the stretchable wiring board 1A is stretched in the length direction L, it is possible to prompt the user to stop using the stretchable wiring board 1A before the first wiring portion 20Aa excessively generates heat due to the first wiring portion 20Aa being excessively stretched in the length direction L. For this reason, when the stretchable wiring board 1A is used, not only excessive heat generation of the first wiring portion 20Aa, but also exposure of excessive heat generated in the first wiring portion 20Aa to the body of the user are prevented, and as a result, safety is enhanced.

As described above, according to the stretchable wiring board 1A, it is possible to realize a stretchable wiring board that allows an excessively stretched state to be safely detected.

As described above, the narrow portion 11A corresponds to a portion having a smallest sectional area when a section orthogonal to the length direction L is viewed in the stretchable substrate 10A. For this reason, when the stretchable wiring board 1A is stretched in the length direction L, in the stretchable substrate 10A, stress tends to concentrate on the narrow portion 11A, and as a result, the narrow portion 11A tends to stretch more than other portions.

On the other hand, in the stretchable wiring board 1A, the second wiring portion 20Ab is provided at a position overlapping the narrow portion 11A when viewed from the thickness direction T. That is, in the stretchable wiring board 1A, the second wiring portion 20Ab that is first disconnected when the wiring member 20A is stretched in the length direction L is provided in the narrow portion 11A that is most stretched when the stretchable substrate 10A is stretched in the length direction L. Therefore, according to the stretchable wiring board 1A in which the second wiring portion 20Ab is provided in the narrow portion 11A, when the stretchable wiring board 1A is stretched in the length direction L, the second wiring portion 20Ab is more likely to be disconnected at an early stage as compared with a stretchable wiring board in which the second wiring portion 20Ab is not provided in the narrow portion 11A, and for this reason, in addition to making it easier to detect an excessively stretched state of the entire stretchable wiring board, an excessively stretched state of the stretchable wiring board can be detected at an earlier stage.

In the example illustrated in FIG. 1, the second wiring portion 20Ab is provided at a position not overlapping the narrow portion 11A when viewed from the thickness direction T, in addition to a position overlapping the narrow portion 11A when viewed from the thickness direction T.

Note that the second wiring portion 20Ab may be provided only at a position overlapping the narrow portion 11A when viewed from the thickness direction T.

In the example illustrated in FIG. 1, in the stretchable substrate 10A, only one of the narrow portion 11A exists, but the narrow portions 11A may exist in a plurality of places. In a case where a plurality of narrow portions 11A exist in the stretchable substrate 10A, the second wiring portion 20Ab is preferably provided at a position overlapping each of the narrow portions 11A when viewed from the thickness direction T. In this case, disconnection of the second wiring portion 20Ab overlapping each of the narrow portions 11A can be more easily detected, so that an excessively stretched state of the entire stretchable wiring board 1A can be reliably detected.

Note that in a case where a plurality of the narrow portions 11A exist in the stretchable substrate 10A, the second wiring portion 20Ab may be provided at positions overlapping some of the narrow portions 11A when viewed from the thickness direction T.

Note that, for example, in a case where the narrow portion 11A is fixed to a human body with a reinforcing material such as resin, there is a possibility that the narrow portion 11A is not a portion that stretches the most when the stretchable substrate 10A is stretched in the length direction L. As described above, in a case where the narrow portion 11A is not a portion that stretches the most in the stretchable substrate 10A, by providing the second wiring portion 20Ab at a position overlapping a portion that is mechanically softest and stretches most in the entire stretchable substrate 10A as viewed in the thickness direction T, an excessively stretched state of the entire stretchable wiring board 1A can be easily detected, and in addition, an excessively stretched state of the stretchable wiring board 1A can be detected at an earlier stage.

In the example illustrated in FIG. 1, the second wiring portion 20Ab is provided so as to surround the first wiring portion 20Aa when viewed from the thickness direction T. That is, in the example illustrated in FIG. 1, when viewed from the thickness direction T, the second wiring portion 20Ab is provided outside the first wiring portion 20Aa, more specifically, further on the outer edge side of the stretchable substrate 10A than the first wiring portion 20Aa. As illustrated in FIG. 1, when the second wiring portion 20Ab is provided on an outer edge of the stretchable substrate 10A, a region where an excessively stretched state of the stretchable wiring board 1A can be detected is widened by the second wiring portion 20Ab, so that an excessively stretched state of the stretchable wiring board 1A can be easily detected.

Note that, when viewed from the thickness direction T, the second wiring portion 20Ab does not need to be provided so as to surround the first wiring portion 20Aa. That is, when viewed from the thickness direction T, the second wiring portion 20Ab does not need to be provided outside the first wiring portion 20Aa, more specifically, further on the outer edge side of the stretchable substrate 10A than the first wiring portion 20Aa.

In the example illustrated in FIG. 1, the second wiring portion 20Ab is not electrically connected to an electronic component. That is, in the example illustrated in FIG. 1, the second wiring portion 20Ab does not constitute an electric path to an external electronic component. In this case, disconnection of the second wiring portion 20Ab can be detected by connecting a terminal of a resistance meter (not an electronic component) which is a measuring instrument to the second wiring portion 20Ab and measuring resistance of the second wiring portion 20Ab as needed.

Note that the second wiring portion 20Ab may be electrically connected to an electronic component. That is, the second wiring portion 20Ab may constitute an electric path to an external electronic component. In this case, by using, for example, a light emitting diode as an electronic component electrically connected to the second wiring portion 20Ab, it is possible to constantly check whether or not the second wiring portion 20Ab is disconnected based on whether or not the light emitting diode is lit.

Hereinafter, description will be made on an example of an aspect in which, in the wiring member 20A, tensile strength in the length direction L of the second wiring portion 20Ab is lower than tensile strength in the length direction L of a portion other than the second wiring portion 20Ab including the first wiring portion 20Aa, that is, lower than tensile strength in the length direction L of the first wiring portion 20Aa.

When a section orthogonal to the length direction L of the wiring member 20A is viewed, a sectional area of the second wiring portion 20Ab is preferably smaller than a sectional area of the first wiring portion 20Aa.

In a case where a sectional area of the second wiring portion 20Ab is smaller than a sectional area of the first wiring portion 20Aa, the sectional area of the second wiring portion 20Ab is preferably 10% to 90% of the sectional area of the first wiring portion 20Aa.

When a section orthogonal to the length direction L of the wiring member 20A is viewed, in the wiring member 20A, a sectional area of the second wiring portion 20Ab is preferably smaller than a sectional area of a portion other than the second wiring portion 20Ab including the first wiring portion 20Aa.

In the stretchable wiring board 1A, a relationship between a sectional area of a wiring portion and a breaking elongation rate in the length direction L of the wiring portion is grasped in advance, and then a sectional area of the second wiring portion 20Ab is set as described above, so that a timing at which the second wiring portion 20Ab is disconnected when the stretchable wiring board 1A is stretched in the length direction L, that is, a timing at which an excessively stretched state of the stretchable wiring board 1A is detected can be adjusted.

Note that sectional areas of the first wiring portion 20Aa and the second wiring portion 20Ab may be the same.

A dimension in the width direction W of the second wiring portion 20Ab is preferably smaller than a dimension in the width direction W of the first wiring portion 20Aa. In this case, for example, if dimensions in the thickness direction T of the first wiring portion 20Aa and the second wiring portion 20Ab are the same, a sectional area of the second wiring portion 20Ab can be made smaller than a sectional area of the first wiring portion 20Aa.

In a case where a dimension in the width direction W of the second wiring portion 20Ab is smaller than a dimension in the width direction W of the first wiring portion 20Aa, the dimension in the width direction W of the second wiring portion 20Ab is preferably 10% to 90% of the dimension in the width direction W of the first wiring portion 20Aa.

In the wiring member 20A, a dimension in the width direction W of the second wiring portion 20Ab is preferably smaller than a dimension in the width direction W of a portion other than the second wiring portion 20Ab including the first wiring portion 20Aa.

In the stretchable wiring board 1A, a relationship between a dimension in the width direction W of a wiring portion and a breaking elongation rate in the length direction L of the wiring portion is grasped in advance, and then a dimension in the width direction W of the second wiring portion 20Ab is set as described above, so that a timing at which the second wiring portion 20Ab is disconnected when the stretchable wiring board 1A is stretched in the length direction L, that is, a timing at which an excessively stretched state of the stretchable wiring board 1A is detected can be adjusted.

Note that dimensions in the width direction W of the first wiring portion 20Aa and the second wiring portion 20Ab may be the same. In this case, since the first wiring portion 20Aa and the second wiring portion 20Ab are easily formed under the same condition, manufacturing efficiency of the stretchable wiring board 1A is easily improved.

A dimension in the thickness direction T of the second wiring portion 20Ab is preferably smaller than a dimension in the thickness direction T of the first wiring portion 20Aa. In this case, for example, if dimensions in the width direction W of the first wiring portion 20Aa and the second wiring portion 20Ab are the same, a sectional area of the second wiring portion 20Ab can be made smaller than a sectional area of the first wiring portion 20Aa.

In a case where a dimension in the thickness direction T of the second wiring portion 20Ab is smaller than a dimension in the thickness direction T of the first wiring portion 20Aa, the dimension in the thickness direction T of the second wiring portion 20Ab is preferably 30% to 90% of the dimension in the thickness direction T of the first wiring portion 20Aa.

In the wiring member 20A, a dimension in the thickness direction T of the second wiring portion 20Ab is preferably smaller than a dimension in the thickness direction T of a portion other than the second wiring portion 20Ab including the first wiring portion 20Aa.

In the stretchable wiring board 1A, a relationship between a dimension in the thickness direction T of a wiring portion and a breaking elongation rate in the length direction L of the wiring portion is grasped in advance, and then a dimension in the thickness direction T of the second wiring portion 20Ab is set as described above, so that a timing at which the second wiring portion 20Ab is disconnected when the stretchable wiring board 1A is stretched in the length direction L, that is, a timing at which an excessively stretched state of the stretchable wiring board 1A is detected can be adjusted.

Note that dimensions in the thickness direction T of the first wiring portion 20Aa and the second wiring portion 20Ab may be the same. In this case, since the first wiring portion 20Aa and the second wiring portion 20Ab are easily formed under the same condition such as using the same screen printing plate, for example, manufacturing efficiency of the stretchable wiring board 1A is easily improved.

In a case where the stretchable wiring 21Aa, the stretchable wiring 21Ab, and the stretchable wiring 21Ac are formed by applying conductive paste by a screen printing method or the like, dimensions in the thickness direction T of the first wiring portion 20Aa and the second wiring portion 20Ab can be adjusted by means such as applying the conductive paste a plurality of times.

A constituent material of the second wiring portion 20Ab may be different from a constituent material of the first wiring portion 20Aa. In this case, stretchability of the constituent material of the second wiring portion 20Ab is preferably lower than the stretchability of the constituent material of the first wiring portion 20Aa. Further, an elongation rate of the constituent material of the second wiring portion 20Ab is preferably lower than an elongation rate of the constituent material of the first wiring portion 20Aa when the same load is applied. In these cases, for example, if sectional areas of the first wiring portion 20Aa and the second wiring portion 20Ab are the same, tensile strength in the length direction L of the second wiring portion 20Ab can be made lower than tensile strength in the length direction L of the first wiring portion 20Aa. For example, by forming the second wiring portion 20Ab by using thermosetting paste having a generally low breaking elongation rate, a breaking elongation rate in the length direction L of the second wiring portion 20Ab can be adjusted to be low, so that tensile strength in the length direction L of the second wiring portion 20Ab can be made lower than tensile strength in the length direction L of the first wiring portion 20Aa. As described above, by using the second wiring portion 20Ab in which a breaking elongation rate in the length direction L is adjusted to be low, it is possible to detect a small stretched state of the stretchable wiring board 1A.

In the wiring member 20A, stretchability of a constituent material of the second wiring portion 20Ab is preferably lower than stretchability of a constituent material of a portion other than the second wiring portion 20Ab including the first wiring portion 20Aa. Further, in the wiring member 20A, an elongation rate of a constituent material of the second wiring portion 20Ab is preferably lower than an elongation rate of a constituent material of a portion other than the second wiring portion 20Ab including the first wiring portion 20Aa when the same load is applied.

A breaking elongation rate in the length direction L of the second wiring portion 20Ab is preferably lower than a breaking elongation rate in the length direction L of the first wiring portion 20Aa.

A breaking elongation rate in the length direction L of the second wiring portion 20Ab is preferably 10% to 90% of a breaking elongation rate in the length direction L of the first wiring portion 20Aa.

In the wiring member 20A, a breaking elongation rate in the length direction L of the second wiring portion 20Ab is preferably lower than a breaking elongation rate in the length direction L of a portion other than the second wiring portion 20Ab including the first wiring portion 20Aa.

The stretchable wiring board 1A may further include an electrode connected to the first wiring portion 20Aa, at least one of the stretchable wiring 21Aa and the stretchable wiring 21Ab in the example illustrated in FIG. 1. The stretchable wiring board 1A can function as a sensor by being attached to a human body with such an electrode interposed therebetween. In this case, according to the stretchable wiring board 1A, for example, it is possible to detect that the stretchable wiring board 1A is in an excessively stretched state before disconnection occurs due to the first wiring portion 20Aa being excessively stretched in the length direction L, that is, before abnormality of a sensor occurs. By the above, it is possible to prompt the user to stop using the stretchable wiring board 1A before abnormality of a sensor occurs, so that it is possible to prevent problems such as acquisition of erroneous biological information and diagnosis based on erroneous biological information.

The electrode is preferably a gel electrode. The stretchable wiring board 1A is easily attached to a human body via a gel electrode. The gel electrode includes, for example, a conductive gel material containing water, alcohol, a humectant, an electrolyte, and the like. Examples of such a gel material include hydrogel.

### Variation of First Embodiment

The stretchable wiring board according to a variation of the first embodiment of the present disclosure further includes a protective member that covers at least one of a first main surface and a second main surface of a stretchable substrate. Except for this point, the stretchable wiring board according to the variation of the first embodiment of the present disclosure is the same as the stretchable wiring board according to the first embodiment of the present disclosure.

FIG. 2 is a schematic perspective view illustrating an example of the stretchable wiring board according to the variation of the first embodiment of the present disclosure.

A stretchable wiring board 1A′ illustrated in FIG. 2 further includes a protective member 40A in addition to the stretchable substrate 10A and the wiring member 20A.

The protective member 40A covers at least one of the first main surface 10Aa and the second main surface 10Ab of the stretchable substrate 10A.

In the example illustrated in FIG. 2, the protective member 40A covers both the first main surface 10Aa and the second main surface 10Ab of the stretchable substrate 10A.

Note that the protective member 40A may cover only the first main surface 10Aa of the stretchable substrate 10A, or may cover only the second main surface 10Ab of the stretchable substrate 10A.

In the example illustrated in FIG. 2, the protective member 40A includes a first protective portion 40Aa and a second protective portion 40Ab. In the example illustrated in FIG. 2, the first protective portion 40Aa covers the first main surface 10Aa of the stretchable substrate 10A, and the second protective portion 40Ab covers the second main surface 10Ab of the stretchable substrate 10A.

In the example illustrated in FIG. 2, the protective member 40A, more specifically, the first protective portion 40Aa covers the wiring member 20A and the electronic component 30 while covering the first main surface 10Aa of the stretchable substrate 10A. Since the protective member 40A covers the wiring member 20A and the electronic component 30, an effect below can be obtained.
The wiring member 20A and the electronic component 30 are protected from the outside.
Moisture resistance of the wiring member 20A and the electronic component 30 is improved.
Contact of a chemical substance used for the wiring member 20A and the electronic component 30 with a human body is prevented.
Electric leakage from the wiring member 20A and the electronic component 30 to a human body is prevented.

Tensile strength in the length direction L of the protective member 40A and tensile strength in the length direction L of each of the first protective portion 40Aa and the second protective portion 40Ab in the example illustrated in FIG. 2 are preferably higher than tensile strength in the length direction L of the second wiring portion 20Ab. In this case, when the stretchable wiring board 1A′ is stretched in the length direction L, the protective member 40A is not broken before the second wiring portion 20Ab. That is, when the stretchable wiring board 1A′ is stretched in the length direction L, the protective member 40A is not broken at a time point at which disconnection of the second wiring portion 20Ab is detected. For this reason, when the stretchable wiring board 1A′ is used, it is possible to prompt the user to stop using the stretchable wiring board 1A′ at a time point when disconnection of the second wiring portion 20Ab is detected, that is, a time point before a problem such as a chemical substance used for the wiring member 20A and the electronic component 30 comes into contact with a human body or electric leakage from the wiring member 20A and the electronic component 30 to a human body occurs due to breakage of the protective member 40A. As a result, safety when using the stretchable wiring board 1A′ including the protective member 40A is enhanced.

Tensile strength in the length direction L of the protective member 40A and tensile strength in the length direction L of each of the first protective portion 40Aa and the second protective portion 40Ab in the example illustrated in FIG. 2 are preferably higher than tensile strength in the length direction L of the first wiring portion 20Aa, and more preferably higher than tensile strength in the length direction L of all portions in the wiring member 20A.

A breaking elongation rate in the length direction L of the protective member 40A and a breaking elongation rate in the length direction L of each of the first protective portion 40Aa and the second protective portion 40Ab in the example illustrated in FIG. 2 are preferably 200% or more.

A breaking elongation rate in the length direction L of the protective member 40A and a breaking elongation rate in the length direction L of each of the first protective portion 40Aa and the second protective portion 40Ab in the example illustrated in FIG. 2 are preferably 800% or less.

Examples of a constituent material of the protective member 40A, a constituent material of the first protective portion 40Aa and the second protective portion 40Ab in the example illustrated in FIG. 2, include polyvinyl chloride, polyethylene, polystyrene, polycarbonate, polyvinylidene fluoride, polyimide, liquid crystal polymer, polytetrafluoroethylene, phenol resin, epoxy-based resin, urethane-based resin, acrylic-based resin, silicone-based resin, and elastomer-based resin such as styrene-butadiene-based resin.

The protective member 40A is formed, for example, by pressure-bonding a film containing the above-described material to at least one of the first main surface 10Aa and the second main surface 10Ab of the stretchable substrate 10A. Alternatively, the protective member 40A is formed, for example, by applying a slurry containing the above-described material to at least one of the first main surface 10Aa and the second main surface 10Ab of the stretchable substrate 10A, and then subjecting the applied slurry to heat treatment or UV treatment. Examples of a method of applying slurry include a screen printing method, an inkjet method, and a dispensing method.

### Second Embodiment

In the stretchable wiring board according to the second embodiment of the present disclosure, the second wiring portion is provided only at a position overlapping the narrow portion when viewed from the thickness direction. Except for this point, the stretchable wiring board according to the second embodiment of the present disclosure is the same as the stretchable wiring board according to the first embodiment of the present disclosure.

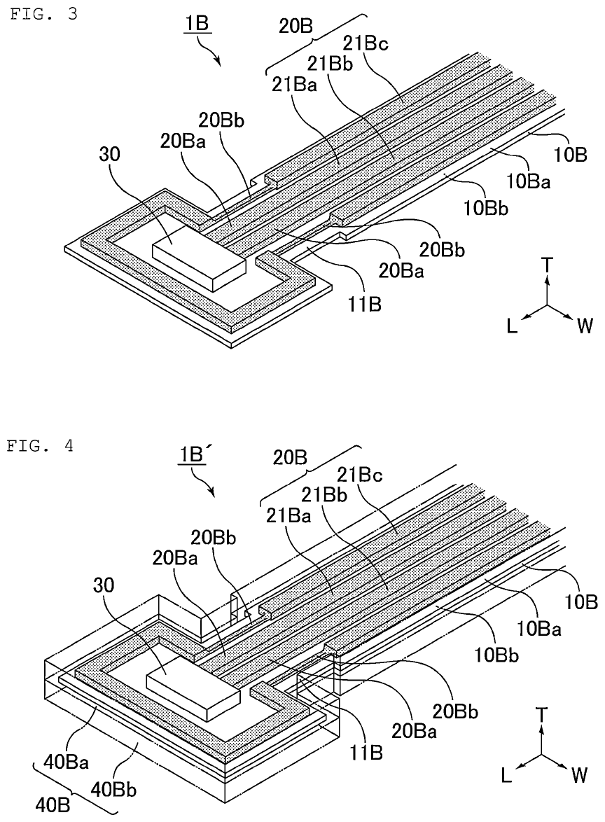

FIG. 3 is a perspective view schematically illustrating an example of the stretchable wiring board of the second embodiment of the present disclosure.

A stretchable wiring board 1B illustrated in FIG. 3 includes a stretchable substrate 10B and a wiring member 20B.

The stretchable substrate 10B has a first main surface 10Ba and a second main surface 10Bb facing each other in the thickness direction T.

The stretchable substrate 10B has a narrow portion 11B having a smallest sectional area when a section orthogonal to the length direction L is viewed.

In the example illustrated in FIG. 3, the wiring member 20B is provided on the first main surface 10Ba side of the stretchable substrate 10B.

In the example illustrated in FIG. 3, the wiring member 20B includes three stretchable wirings 21Ba, 21Bb, and 21Bc stretching in the plane direction.

The wiring member 20B includes a first wiring portion 20Ba and a second wiring portion 20Bb both stretching in the length direction L.

The first wiring portion 20Ba and the second wiring portion 20Bb are provided on different stretchable wirings.

In the example illustrated in FIG. 3, the first wiring portion 20Ba is provided on the stretchable wiring 21Ba and the stretchable wiring 21Bb, and the second wiring portion 20Bb is provided on the stretchable wiring 21Bc. More specifically, the first wiring portion 20Ba corresponds to the entire stretchable wiring 21Ba and stretchable wiring 21Bb, and the second wiring portion 20Bb corresponds to a part of the stretchable wiring 21Bc.

In the stretchable wiring 21Bc, the second wiring portion 20Bb only needs to be electrically connected to a wiring portion adjacent to the second wiring portion 20Bb. In the stretchable wiring 21Bc, the second wiring portion 20Bb may be integrated with a wiring portion adjacent to the second wiring portion 20Bb in a manner that an interface does not appear, or does not need to be integrated with the wiring portion adjacent to the second wiring portion 20Bb in a manner that an interface appears.

The first wiring portion 20Ba, each of the stretchable wiring 21Ba and the stretchable wiring 21Bb in the example illustrated in FIG. 3, is electrically connected to the electronic component 30. That is, the first wiring portion 20Ba constitutes an electric path to the outside, that is, an electric path to the external electronic component 30 in the example illustrated in FIG. 3.

In the wiring member 20B, tensile strength in the length direction L of the second wiring portion 20Bb is lower than tensile strength in the length direction L of a portion other than the second wiring portion 20Bb including the first wiring portion 20Ba. That is, tensile strength in the length direction L of the second wiring portion 20Bb is not only lower than tensile strength in the length direction L of the first wiring portion 20Ba, but also lowest among tensile strengths in the length direction L of the wiring member 20B. By the above, when the stretchable wiring board 1B is stretched in the length direction L, the second wiring portion 20Bb is not only disconnected earlier than the first wiring portion 20Ba, but also disconnected first in the wiring member 20B.

Therefore, according to the stretchable wiring board 1B, by utilizing the fact that the second wiring portion 20Bb is first disconnected when the stretchable wiring board 1B is stretched in the length direction L, it is possible to realize a stretchable wiring board that allows an excessively stretched state to be safely detected, similarly to the stretchable wiring board 1A.

As described above, the narrow portion 11B corresponds to a portion having a smallest sectional area when a section orthogonal to the length direction L is viewed in the stretchable substrate 10B. For this reason, when the stretchable wiring board 1B is stretched in the length direction L, in the stretchable substrate 10B, stress tends to concentrate on the narrow portion 11B, and as a result, the narrow portion 11B tends to stretch more than other portions.

On the other hand, in the stretchable wiring board 1B, the second wiring portion 20Bb is provided only at a position overlapping the narrow portion 11B when viewed from the thickness direction T. Therefore, according to the stretchable wiring board 1B, similarly to the stretchable wiring board 1A, the second wiring portion 20Bb is likely to be disconnected at an earlier stage when the stretchable wiring board 1B is stretched in the length direction L, so that an excessively stretched state can be detected at an earlier stage.

When a section orthogonal to the length direction L of the wiring member 20B is viewed, in the stretchable wiring 21Bc, a sectional area of the second wiring portion 20Bb is preferably smaller than a sectional area of a portion other than the second wiring portion 20Bb.

In the stretchable wiring 21Bc, in a case where a sectional area of the second wiring portion 20Bb is smaller than a sectional area of a portion other than the second wiring portion 20Bb, the sectional area of the second wiring portion 20Bb is preferably 10% to 90% of the sectional area of the portion other than the second wiring portion 20Bb.

In the stretchable wiring 21Bc, a dimension in the width direction W of the second wiring portion 20Bb is preferably smaller than a dimension in the width direction W of a portion other than the second wiring portion 20Bb.

In the stretchable wiring 21Bc, in a case where a dimension in the width direction W of the second wiring portion 20Bb is smaller than a dimension in the width direction W of a portion other than the second wiring portion 20Bb, the dimension in the width direction W of the second wiring portion 20Bb is preferably 10% to 90% of the dimension in the width direction W of the portion other than the second wiring portion 20Bb.

In the stretchable wiring 21Bc, a dimension in the thickness direction T of the second wiring portion 20Bb is preferably smaller than a dimension in the thickness direction T of a portion other than the second wiring portion 20Bb.

In the stretchable wiring 21Bc, in a case where a dimension in the thickness direction T of the second wiring portion 20Bb is smaller than a dimension in the thickness direction T of a portion other than the second wiring portion 20Bb, the dimension in the thickness direction T of the second wiring portion 20Bb is preferably 30% to 90% of the dimension in the thickness direction T of the portion other than the second wiring portion 20Bb.

In the example illustrated in FIG. 3, the second wiring portions 20Bb are provided at two places overlapping the narrow portion 11B when viewed from the thickness direction T, but may be provided at only one place or at three or more places.

In the example illustrated in FIG. 3, dimensions in the length direction L of the second wiring portions 20Bb provided at two places may be the same as or different from each other.

### Variation of Second Embodiment

The stretchable wiring board according to a variation of the second embodiment of the present disclosure further includes a protective member that covers at least one of a first main surface and a second main surface of a stretchable substrate. Except for this point, the stretchable wiring board according to the variation of the second embodiment of the present disclosure is the same as the stretchable wiring board according to the second embodiment of the present disclosure.

FIG. 4 is a schematic perspective view illustrating an example of the stretchable wiring board according to the variation of the second embodiment of the present disclosure.

A stretchable wiring board 1B′ illustrated in FIG. 4 further includes a protective member 40B in addition to the stretchable substrate 10B and the wiring member 20B.

In the example illustrated in FIG. 4, the protective member 40B covers both the first main surface 10Ba and the second main surface 10Bb of the stretchable substrate 10B.

In the example illustrated in FIG. 4, the protective member 40B includes a first protective portion 40Ba and a second protective portion 40Bb. In the example illustrated in FIG. 4, the first protective portion 40Ba covers the first main surface 10Ba of the stretchable substrate 10B, and the second protective portion 40Bb covers the second main surface 10Bb of the stretchable substrate 10B.

### Third Embodiment

In the stretchable wiring board according to the third embodiment of the present disclosure, the first wiring portion and the second wiring portion are provided on the same stretchable wiring. Except for this point, the stretchable wiring board according to the third embodiment of the present disclosure is the same as the stretchable wiring board according to the first embodiment of the present disclosure.

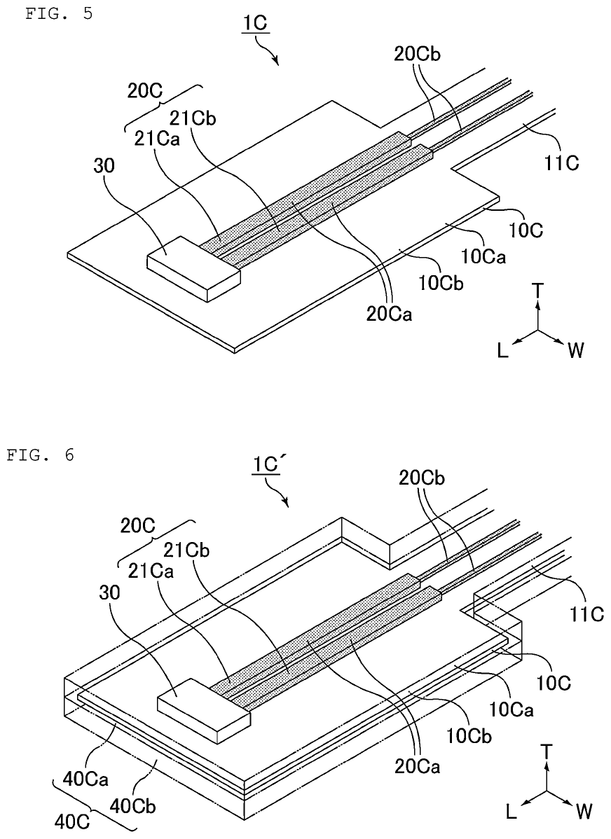

FIG. 5 is a perspective view schematically illustrating an example of the stretchable wiring board of the third embodiment of the present disclosure.

A stretchable wiring board 1C illustrated in FIG. 5 includes a stretchable substrate 10C and a wiring member 20C.

The stretchable substrate 10C has a first main surface 10Ca and a second main surface 10Cb facing each other in the thickness direction T.

In the example illustrated in FIG. 5, the wiring member 20C is provided on the first main surface 10Ca side of the stretchable substrate 10C.

In the example illustrated in FIG. 5, the wiring member 20C includes two stretchable wirings 21Ca and 21Cb stretching in the plane direction.

The wiring member 20C includes a first wiring portion 20Ca and a second wiring portion 20Cb both stretching in the length direction L.

The first wiring portion 20Ca and the second wiring portion 20Cb are provided on the same stretchable wiring.

In the example illustrated in FIG. 5, the first wiring portion 20Ca and the second wiring portion 20Cb are provided in the stretchable wiring 21Ca, and are also provided in the stretchable wiring 21Cb. More specifically, the first wiring portion 20Ca corresponds to a part of each of the stretchable wiring 21Ca and the stretchable wiring 21Cb, and the second wiring portion 20Cb corresponds to a remaining portion of each of the stretchable wiring 21Ca and the stretchable wiring 21Cb.

In each of the stretchable wiring 21Ca and the stretchable wiring 21Cb, the second wiring portion 20Cb only needs to be electrically connected to the first wiring portion 20Ca. In each of the stretchable wiring 21Ca and the stretchable wiring 21Cb, the second wiring portion 20Cb may be integrated with the first wiring portion 20Ca in a manner that an interface does not appear, or may not be integrated with the first wiring portion 20Ca in a manner that an interface appears.

The first wiring portion 20Ca is electrically connected to the electronic component 30. That is, the first wiring portion 20Ca constitutes an electric path to the outside, that is, an electric path to the external electronic component 30 in the example illustrated in FIG. 5.

The second wiring portion 20Cb is connected to the first wiring portion 20Ca.

In the wiring member 20C, tensile strength in the length direction L of the second wiring portion 20Cb is lower than tensile strength in the length direction L of a portion other than the second wiring portion 20Cb including the first wiring portion 20Ca. That is, tensile strength in the length direction L of the second wiring portion 20Cb is not only lower than tensile strength in the length direction L of the first wiring portion 20Ca, but also lowest among tensile strengths in the length direction L of the wiring member 20C. By the above, when the stretchable wiring board 1C is stretched in the length direction L, the second wiring portion 20Cb is not only disconnected earlier than the first wiring portion 20Ca, but also disconnected first in the wiring member 20C.

Therefore, according to the stretchable wiring board 1C, by utilizing the fact that the second wiring portion 20Cb is first disconnected when the stretchable wiring board 1C is stretched in the length direction L, it is possible to realize a stretchable wiring board that allows an excessively stretched state to be safely detected, similarly to the stretchable wiring board 1A.

A dimension in the length direction L of the second wiring portion 20Cb is preferably 1% to 50% of a dimension in the length direction L of the first wiring portion 20Ca. Since the dimension in the length direction L of the second wiring portion 20Cb is in the above range with respect to the dimension in the length direction L of the first wiring portion 20Ca, it is easy to detect an excessively stretched state of the stretchable wiring board 1C, and it is easy to design resistance of the stretchable wiring.

In the example illustrated in FIG. 5, the stretchable substrate 10C has a narrow portion 11C having a smallest sectional area when a section orthogonal to the length direction L is viewed, and the second wiring portion 20Cb is provided at a position overlapping the narrow portion 11C when viewed from the thickness direction T. Therefore, according to the stretchable wiring board 1C, similarly to the stretchable wiring board 1A, the second wiring portion 20Cb is likely to be disconnected at an earlier stage when the stretchable wiring board 1C is stretched in the length direction L, so that an excessively stretched state can be detected at an earlier stage.

In the example illustrated in FIG. 5, the second wiring portions 20Cb are provided at two places overlapping the narrow portion 11C when viewed from the thickness direction T, but may be provided at only one place or at three or more places.

In the example illustrated in FIG. 5, dimensions in the length direction L of the second wiring portions 20Cb provided at two places may be the same as or different from each other.

### Variation of Third Embodiment

The stretchable wiring board according to a variation of the third embodiment of the present disclosure further includes a protective member that covers at least one of a first main surface and a second main surface of a stretchable substrate. Except for this point, the stretchable wiring board according to the variation of the third embodiment of the present disclosure is the same as the stretchable wiring board according to the third embodiment of the present disclosure.

FIG. 6 is a schematic perspective view illustrating an example of the stretchable wiring board according to the variation of the third embodiment of the present disclosure.

A stretchable wiring board 1C′ illustrated in FIG. 6 further includes a protective member 40C in addition to the stretchable substrate 10C and the wiring member 20C.

In the example illustrated in FIG. 6, the protective member 40C covers both the first main surface 10Ca and the second main surface 10Cb of the stretchable substrate 10C.

In the example illustrated in FIG. 6, the protective member 40C includes a first protective portion 40Ca and a second protective portion 40Cb. In the example illustrated in FIG. 6, the first protective portion 40Ca covers the first main surface 10Ca of the stretchable substrate 10C, and the second protective portion 40Cb covers the second main surface 10Cb of the stretchable substrate 10C.

### Fourth Embodiment

The stretchable wiring board according to the fourth embodiment of the present disclosure further includes a detection unit that checks an energization state of a second wiring portion during use of the stretchable wiring board, a determination unit that determines whether or not the second wiring portion is disconnected based on information on the energization state of the second wiring portion checked by the detection unit, and a transmission unit that transmits information indicating that disconnection of the second wiring portion is detected.

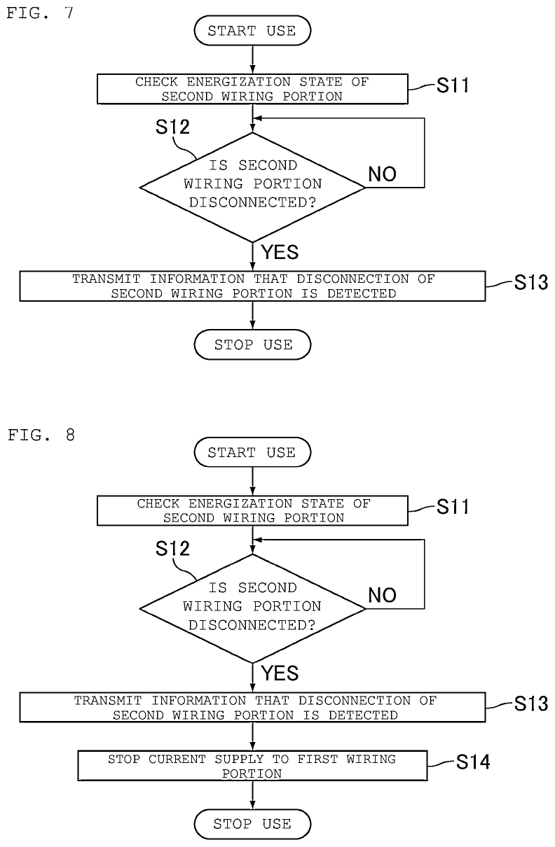

FIG. 7 is a flowchart illustrating an example of operation of the stretchable wiring board according to the fourth embodiment of the present disclosure.

First, the user starts using the stretchable wiring board attached to his or her body. At this time, the stretchable wiring board is stretched in the length direction.

Next, in Step S11 illustrated in FIG. 7, the detection unit checks an energization state of the second wiring portion during use of the stretchable wiring board.

At this time, for example, an energization state of the second wiring portion may be checked by measuring resistance of the second wiring portion as needed by using a resistance meter as the detection unit.

Further, for example, a detection circuit in which a light emitting diode is connected to the second wiring portion may be provided as the detection unit, and an energization state of the second wiring portion may be checked by checking a lighting state of the light emitting diode as needed.

Next, in Step S12 illustrated in FIG. 7, the determination unit determines whether or not the second wiring portion is disconnected based on information on an energization state of the second wiring portion checked by the detection unit.

At this time, for example, in a case where resistance of the second wiring portion is measured as needed by using a resistance meter as the detection unit, the determination unit may determine that the second wiring portion is disconnected when resistance of the second wiring portion becomes equal to or more than a threshold.

Further, for example, in a case where a detection circuit in which a light emitting diode is connected to the second wiring portion is provided as the detection unit and a lighting state of the light emitting diode is checked as needed, the determination unit may determine that the second wiring portion is disconnected when the light emitting diode is switched from an on state to an off state.

The determination unit may be, for example, a determination circuit connected to a resistance meter as the detection unit, a detection circuit, or the like.

Note that in a case where it is not determined that the second wiring portion is disconnected, the determination processing by the determination unit in Step S12 described above is performed again.

Next, in a case where the determination unit determines that the second wiring portion is disconnected, the transmission unit transmits information indicating that disconnection of the second wiring portion is detected in Step S13 illustrated in FIG. 7.

At this time, for example, in a case where a detection circuit in which a light emitting diode is connected to the second wiring portion is provided as the detection unit, information indicating that disconnection of the second wiring portion is detected may be transmitted by showing to the user that the light emitting diode is switched from an on state to an off state. In this case, the light emitting diode connected to the second wiring portion functions as the transmission unit.

Further, for example, an alert circuit that transmits an alert when the second wiring portion is disconnected may be provided as the transmission unit, and the alert transmitted by the alert circuit may be shown to the user so as to transmit information indicating that disconnection of the second wiring portion is detected. Examples of a mode of transmitting an alert include displaying an alert message on a monitor or the like, generating an alert sound, turning on an alarm lamp, and the like.

The user can stop using the stretchable wiring board by checking information that disconnection of the second wiring portion is detected, which is transmitted from the transmission unit in Step S13. By the above, use of the stretchable wiring board can be stopped at a time point at which disconnection of the second wiring portion is detected, that is, at a time point before the first wiring portion is excessively stretched in the length direction.

### Variation of Fourth Embodiment

The stretchable wiring board according to a variation of the fourth embodiment of the present disclosure further includes a control unit that stops current supply to the first wiring portion in conjunction with the transmission unit transmitting information that disconnection of the second wiring portion is detected. Except for this point, the stretchable wiring board according to the variation of the fourth embodiment of the present disclosure is the same as the stretchable wiring board according to the fourth embodiment of the present disclosure.

FIG. 8 is a flowchart illustrating an example of operation of the stretchable wiring board according to the variation of the fourth embodiment of the present disclosure.

Steps S11, S12, and S13 illustrated in FIG. 8 are similar to those in FIG. 7.

Next, in Step S14 illustrated in FIG. 8, the control unit stops current supply to the first wiring portion in conjunction with the transmission unit transmitting information that disconnection of the second wiring portion is detected.

The control unit may be, for example, a control circuit that can stop current supply to the first wiring portion in conjunction with the transmission unit transmitting information that disconnection of the second wiring portion is detected. The control circuit may be directly connected to the first wiring portion or may not be directly connected to the first wiring portion.

A timing at which the control unit stops current supply to the first wiring portion may be the same timing as a timing at which the transmission unit transmits information that disconnection of the second wiring portion is detected, or may be a timing after the transmission unit transmits information that disconnection of the second wiring portion is detected.

In Step S14, the control unit stops current supply to the first wiring portion, so that use of the stretchable wiring board can be stopped forcibly. By the above, use of the stretchable wiring board can be reliably stopped at a time point at which disconnection of the second wiring portion is detected, that is, at a time point before the first wiring portion is excessively stretched in the length direction.

In each of the above embodiments, an aspect in which the stretchable wiring board is stretched in the length direction when the stretchable wiring board is used is described, but the stretchable wiring board may be stretched in a plane direction (for example, in the width direction) other than the length direction in addition to the length direction.

Content below is disclosed in the present description.

<1> A stretchable wiring board including: a stretchable substrate having a first main surface and a second main surface facing each other in a thickness direction; and a wiring member on at least the first main surface side of the stretchable substrate and including at least one stretchable wiring extending in a plane direction including a length direction orthogonal to the thickness direction and a width direction orthogonal to the thickness direction and the length direction, wherein the at least one stretchable wiring includes a first wiring portion and a second wiring portion both extending in the length direction, at least the first wiring portion is an electric path to an outside of the stretchable wiring board, and a tensile strength in the length direction of the second wiring portion is lower than a tensile strength in the length direction of the first wiring portion.

<2> The stretchable wiring board according to <1>, in which the first wiring portion and the second wiring portion are separate stretchable wirings.

<3> The stretchable wiring board according to <1>, in which the first wiring portion and the second wiring portion are in a same stretchable wiring.

<4> The stretchable wiring board according to <3>, in which a dimension in the length direction of the second wiring portion is 1% to 50% of a dimension in the length direction of the first wiring portion.

<5> The stretchable wiring board according to any of <1> to <4>, in which when a section orthogonal to the length direction of the wiring member is viewed, a sectional area of the second wiring portion is smaller than a sectional area of the first wiring portion.

<6> The stretchable wiring board according to <5>, in which a dimension in the width direction of the second wiring portion is smaller than a dimension in the width direction of the first wiring portion.

<7> The stretchable wiring board according to <5> or <6>, in which a dimension in the thickness direction of the second wiring portion is smaller than a dimension in the thickness direction of the first wiring portion.

<8> The stretchable wiring board according to any of <1> to <7>, in which a constituent material of the second wiring portion is different from a constituent material of the first wiring portion.

<9> The stretchable wiring board according to any of <1> to <8>, in which the stretchable substrate has a narrow portion having a smallest sectional area when a section orthogonal to the length direction is viewed, and the second wiring portion overlaps the narrow portion when viewed from the thickness direction.

<10> The stretchable wiring board according to any of <1> to <9>, further including a protective member that covers at least one of the first main surface and the second main surface of the stretchable substrate.

<11> The stretchable wiring board according to any of <1> to <10>, further including: a detection unit that checks an energization state of the second wiring portion during use of the stretchable wiring board; a determination unit that determines whether or not the second wiring portion is disconnected based on information on the energization state of the second wiring portion checked by the detection unit; and a transmission unit that transmits information that disconnection of the second wiring portion is detected.

<12> The stretchable wiring board according to <11>, further including a control unit that stops current supply to the first wiring portion in conjunction with the transmission unit transmitting the information that disconnection of the second wiring portion is detected.

### DESCRIPTION OF REFERENCE SYMBOLS

1A, 1A′, 1B, 1B′, 1C, 1C′: Stretchable wiring board
10A, 10B, 10C: Stretchable substrate
10Aa, 10Ba, 10Ca: First main surface
10Ab, 10Bb, 10Cb: Second main surface
11A, 11B, 11C: Narrow portion
20A, 20B, 20C: Wiring member
20Aa, 20Ba, 20Ca: First wiring portion
20Ab, 20Bb, 20Cb: Second wiring portion
21Aa, 21Ab, 21Ac, 21Ba, 21Bb, 21Bc, 21Ca, 21Cb: Stretchable wiring
30: Electronic component
40A, 40B, 40C: Protective member
40Aa, 40Ba, 40Ca: First protective portion
40Ab, 40Bb, 40Cb: Second protective portion
L: Length direction
S11, S12, S13, S14: Step
T: Thickness direction
W: Width direction

1. A stretchable wiring board comprising:
a stretchable substrate having a first main surface and a second main surface facing each other in a thickness direction; and
a wiring member on at least the first main surface side of the stretchable substrate and including at least one stretchable wiring extending in a plane direction including a length direction orthogonal to the thickness direction and a width direction orthogonal to the thickness direction and the length direction, wherein
the at least one stretchable wiring includes a first wiring portion and a second wiring portion both extending in the length direction,
at least the first wiring portion is an electric path to an outside of the stretchable wiring board, and
a tensile strength in the length direction of the second wiring portion is lower than a tensile strength in the length direction of the first wiring portion.

2. The stretchable wiring board according to claim 1, wherein the first wiring portion and the second wiring portion are separate stretchable wirings.

3. The stretchable wiring board according to claim 1, wherein the first wiring portion and the second wiring portion are in a same stretchable wiring.

4. The stretchable wiring board according to claim 3, wherein a dimension in the length direction of the second wiring portion is 1% to 50% of a dimension in the length direction of the first wiring portion.

5. The stretchable wiring board according to claim 1, wherein when a section orthogonal to the length direction of the wiring member is viewed, a sectional area of the second wiring portion is smaller than a sectional area of the first wiring portion.

6. The stretchable wiring board according to claim 5, wherein a dimension in the width direction of the second wiring portion is smaller than a dimension in the width direction of the first wiring portion.

7. The stretchable wiring board according to claim 6, wherein the dimension in the width direction of the second wiring portion is 10% to 90% of the dimension in the width direction of the first wiring portion.

8. The stretchable wiring board according to claim 6, wherein a dimension in the thickness direction of the second wiring portion is smaller than a dimension in the thickness direction of the first wiring portion.

9. The stretchable wiring board according to claim 5 wherein a dimension in the thickness direction of the second wiring portion is smaller than a dimension in the thickness direction of the first wiring portion.

10. The stretchable wiring board according to claim 5, wherein the sectional area of the second wiring portion is 10% to 90% of the sectional area of the first wiring portion.

11. The stretchable wiring board according to claim 1, wherein a constituent material of the second wiring portion is different from a constituent material of the first wiring portion.

12. The stretchable wiring board according to claim 11, wherein stretchability of the constituent material of the second wiring portion is lower than stretchability of the constituent material of the first wiring portion.

13. The stretchable wiring board according to claim 1, wherein
the stretchable substrate has a narrow portion having a smallest sectional area when a section orthogonal to the length direction is viewed, and
the second wiring portion overlaps the narrow portion when viewed from the thickness direction.

14. The stretchable wiring board according to claim 1, further comprising a protective member that covers at least one of the first main surface and the second main surface of the stretchable substrate.

15. The stretchable wiring board according to claim 14, wherein a tensile strength in the length direction of the protective member is higher than a tensile strength in the length direction of the second wiring portion.

16. The stretchable wiring board according to claim 1, wherein the second wiring portion surrounds the first wiring portion when viewed in the thickness direction.

17. The stretchable wiring board according to claim 1, wherein a breaking elongation rate in the length direction of the second wiring portion is lower than a breaking elongation rate in the length direction of the first wiring portion.

18. The stretchable wiring board according to claim 16, wherein the breaking elongation rate in the length direction of the second wiring portion is 10% to 90% of the breaking elongation rate in the length direction of the first wiring portion.

19. The stretchable wiring board according to claim 1, further comprising:
a detection unit that checks an energization state of the second wiring portion during use of the stretchable wiring board;
a determination unit that determines whether or not the second wiring portion is disconnected based on information on the energization state of the second wiring portion checked by the detection unit; and
a transmission unit that transmits information that disconnection of the second wiring portion is detected.

20. The stretchable wiring board according to claim 19, further comprising a control unit that stops current supply to the first wiring portion in conjunction with the transmission unit transmitting the information that disconnection of the second wiring portion is detected.
